(19) United States
(12) Patent Application Publication
(10) Pub. No.: US 2024/0208340 A1
(43) Pub. Date: Jun. 27, 2024

(54) CHARGE INLET

(71) Applicant: Yazaki Corporation, Tokyo (JP)

(72) Inventors: Akihiro SAITO, Kakegawa-shi (JP); Shinsuke AOSHIMA, Fujieda-shi (JP)

(73) Assignee: Yazaki Corporation, Tokyo (JP)

(21) Appl. No.: 18/389,902

(22) Filed: Dec. 20, 2023

(30) Foreign Application Priority Data
Dec. 22, 2022 (JP) 2022-205097

(51) Int. Cl. B60L 53/16; H05K 7/20

(52) U.S. Cl. CPC B60L 53/16; H05K 7/20445

(57) ABSTRACT

A charge inlet that can alleviate temperature rise during charging while alleviating the increase in the weight and cost around the inlet and the increase in the size of the inlet is provided. The charge inlet 100 includes a connector terminal 110, a housing 120 in which the connector terminal 110 is inserted in a predetermined insertion direction D11, and a heat-drawing component 130 detachably accommodated in the housing 120 in such a state that the heat-drawing component 130 is in contact, in a contact direction D12 that crosses the insertion direction D11, with an electric wire connection portion 112 (heat source) of the connector terminal 110 that is away, in a direction opposite to the insertion direction D11, from a terminal portion of 111 the connector terminal 110 for connecting with a mating connector terminal, or with an electric wire terminal W111 (intermediate member) that is in contact with the electric wire connection portion 112 (the heat source), the heat-drawing component 130 being configured to absorb heat of the electric wire connection portion 112 of the connector terminal 110 (the heat source).

### TECHNICAL FIELD

The present disclosure relates to a charge inlet in which connector terminals are accommodated in a housing.

### BACKGROUND

A charge inlet is used as a vehicle-side connector for charging a battery mounted in an electric vehicle (EV), a plug-in hybrid electric vehicle (PHV), and the like from an external power source (see, for example, Patent Document 1). The charge inlet has connector terminals accommodated in a housing, and has a mechanism compatible with the charge standard for connecting to a mating connector for charging. In the charge inlet of Patent Document 1, the connector terminals are connected inside the housing to electric wires extending to a battery to be charged.

In recent years, in order to meet the needs for increasing the capacity of batteries charged via charge inlets and shortening the charge time, there has been a trend toward increasing the charge current. As the current increases in the charge inlet, a problem arises mainly in heat generation around the connector terminals. One example of how to deal with such heat generation is to increase the diameter of the electric wires connected to the connector terminals, thereby lowering the connection resistance with the connector terminals and improving the ability of the electric wires to draw heat. In the vicinity of the connector terminals, resistance is high at the contact points with the mating connector terminals, and as a result, heat generation tends to be high. The heat generated in these parts is dissipated by the large-diameter electric wires, thereby alleviating temperature rise during charging.

### RELATED ART

### Patent Document

[Patent Document 1] JP 2018-133278 A

### SUMMARY OF THE INVENTION

### Problem to be Solved by the Invention

However, as the diameter of the electric wires extending from the charge inlet increases due to the countermeasures described above, not only the weight and cost around the inlet increase, but also passing large-diameter electric wires inside may lead to the increase in the inlet size.

Therefore, in view of the above-mentioned problems, it is an object of the present disclosure to provide a charge inlet that can alleviate temperature rise during charging while alleviating the increase in the weight and cost around the inlet and the increase in the size of the inlet.

### Solution to Problem

In order to solve the above problems, a charge inlet includes a connector terminal connected to a mating connector terminal for charging; a housing in which the connector terminal is inserted in a predetermined insertion direction and is accommodated in such a state that the connector terminal can connect to the mating connector terminal; and a heat-drawing component detachably accommodated in the housing in such a state that the heat-drawing component is in contact, in a contact direction that crosses the insertion direction, with a heat source of the connector terminal that is away, in a direction opposite to the insertion direction, from a terminal portion of the connector terminal for connecting with the mating connector terminal, or with an intermediate member that is in contact with the heat source, the heat-drawing component being configured to absorb heat of the heat source when the heat-drawing component is accommodated in the housing.

### Advantageous Effects of the Invention

According to the charge inlet described above, temperature rise during charging can be alleviated while alleviating the increase in the weight and cost around the inlet and the increase in the size of the inlet.

### BRIEF DESCRIPTION OF THE DRAWINGS

FIG. 1 is a plan view of a charge inlet according to an embodiment, as seen from the side from which electric wires extend.

FIG. 2 is a sectional view illustrating a cross section of the charge inlet illustrated in FIG. 1, taken along the line V11-V11 of FIG. 1.

FIG. 3 is a perspective view of how heat-drawing members are attached to the charge inlet illustrated in FIGS. 1 and 2, as seen from the connection side where the charge inlet connects to the mating connector.

FIG. 4 is a cross-sectional view similar to FIG. 2, illustrating how the heat-drawing member illustrated in FIG. 3 is attached.

FIG. 5 is a schematic diagram illustrating how the heat-drawing components illustrated in FIGS. 2 to 4 alleviate temperature rise due to heat during charging.

FIG. 6 is a diagram illustrating a comparative example for comparison with the charge inlet illustrated in FIGS. 1 to 5.

### DETAILED DESCRIPTION OF THE EXEMPLARY EMBODIMENT

An embodiment of a charge inlet is described below.

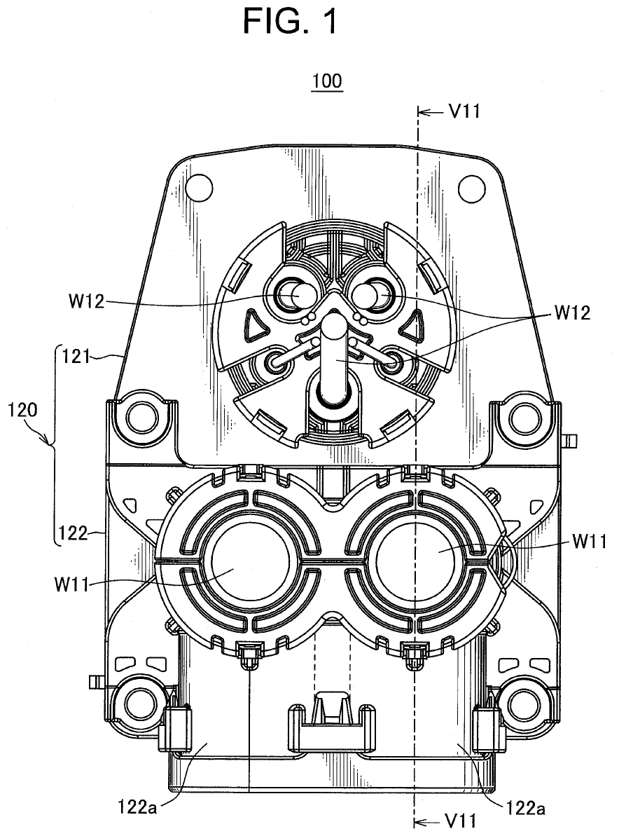

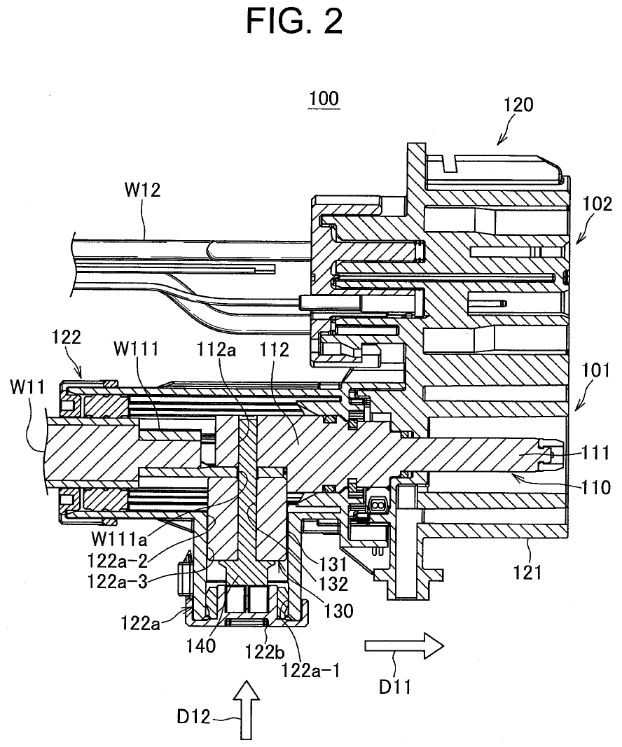

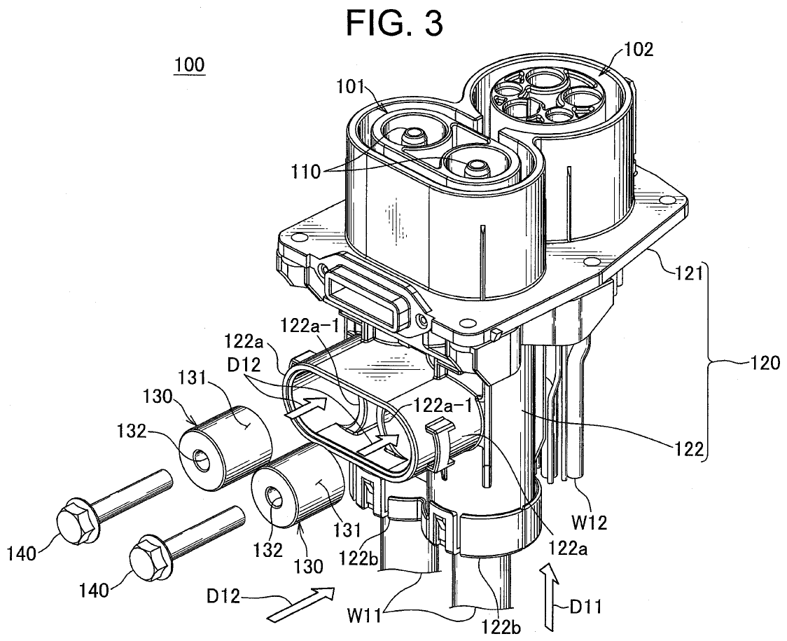

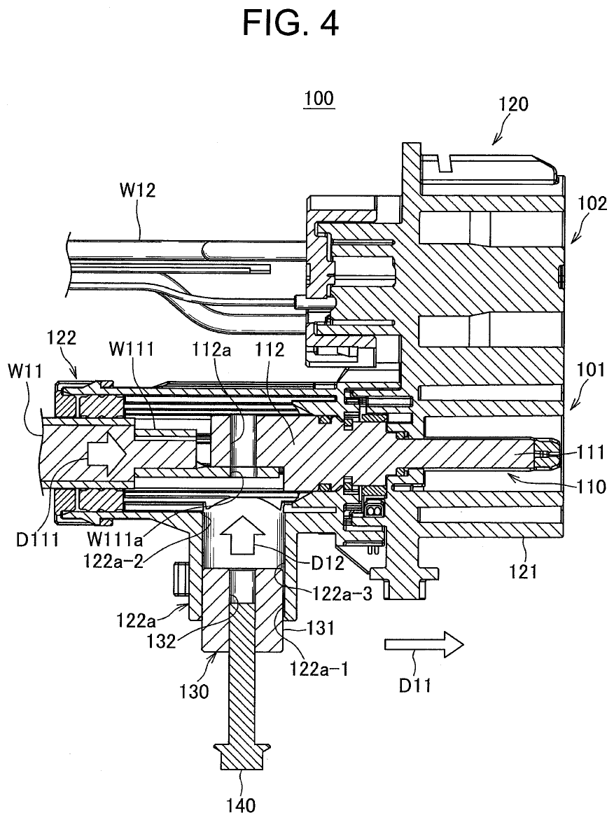

FIG. 1 is a plan view of a charge inlet according to an embodiment, as seen from the side from which electric wires extend. FIG. 2 is a sectional view illustrating a cross section of the charge inlet illustrated in FIG. 1, taken along the line V11-V11 of FIG. 1. FIG. 3 is a perspective view of how heat-drawing members are attached to the charge inlet illustrated in FIGS. 1 and 2, as seen from the connection side where the charge inlet connects to the mating connector. FIG. 4 is a cross-sectional view similar to FIG. 2, illustrating how the heat-drawing member illustrated in FIG. 3 is attached.

The charge inlet 100 is a component used in an electric vehicle (EV), a plug-in hybrid electric vehicle (PHV), and the like, to charge a battery mounted on the vehicle body from an external power source. A DC socket 101 through which a DC charge current for the battery flows, and an AC socket 102 through which an AC current related to charge flows, are provided on the connection side of the charge inlet 100 for the mating connector. DC electric wires W11 for charging that pass a DC charge current flowing through the DC socket 101 and AC electric wires W12 that pass an AC current flowing through the AC socket 102 extend from a side of the charge inlet 100 that is opposite to the above-mentioned connection side. The DC electric wires W11 extend to the battery, and the AC electric wires W12 extend to AC equipment.

Here, the feature of the charge inlet 100 according to this embodiment is in the part related to DC, and the cross-sectional views of FIGS. 2 and 4 illustrate cross-sections taken along the DC socket 101, and the perspective view of FIG. 3 illustrates the appearance as seen from the side of the DC socket 101. The charge inlet 100 will be explained below, focusing on the part related to DC. This charge inlet 100 includes two connector terminals 110, a housing 120, and heat-drawing components 130.

The connector terminals 110 are metal terminals of the DC socket 101 of the charge inlet 100. The connector terminals 110 are connected to the DC electric wires W11 in the charge inlet 100. Each of the connector terminals 110 is a male terminal that includes a round pin-shaped terminal portion 111 to be connected to a mating connector terminal, and a block-shaped wire connection portion 112 connected to the DC electric wire W11 away from the terminal portion 111 in a direction opposite to the insertion direction D11. In the present embodiment, the wire connection portion 112 of the connector terminal 110 is a portion that is fastened, by a bolt 140, to an electric wire terminal W111 provided at an end portion of the DC electric wire W11. At the electric wire connection portion 112, a female screw hole 112a into which this fastening bolt 140 is screwed is formed.

The housing 120 is a resin member in which two connector terminals 110 are inserted in the predetermined insertion direction D11 and accommodated in such a state that the two connector terminals 110 can be connected to mating connector terminals in the DC socket 101. Although the explanation is omitted, this housing 120 also accommodates AC connector terminals in such a state that the AC connector terminals can be connected to mating AC connector terminals in the AC socket 102. This housing 120 includes a main body housing 121 constituting the mating side for mating with the mating connectors and a terminal holder 122 in which the electric wire connection portions 112 of the DC connector terminals 110 are accommodated. In the connector terminals 110, the terminal portions 111 are located inside the main body housing 121, and the electric wire connection portions 112 are located inside the terminal holder 122. The electric wire connection portions 112 are fastened, by the bolts, to the electric wire terminals W111 provided at the end portions of the DC electric wires W11 in the terminal holder 122.

The heat-drawing components 130 are members that are detachably accommodated in the housing 120, and when the heat-drawing components 130 are accommodated in the housing 120, absorb heat generated during charging by the connector terminals 110 and dissipate the heat to the housing 120. The heat-drawing components 130 absorb heat from the electric wire connection portions 112 of the connector terminals 110, i.e., heat sources, and are accommodated in such a manner that the heat-drawing components 130 are in contact with the electric wire terminals W111, i.e., intermediate members that are in contact with the electric wire connection portions 112, in a contact direction D12 that crosses the insertion direction D11. The heat-drawing components 130 absorb heat from the electric wire connection portions 112 when the heat-drawing components 130 are accommodated in the housing 120.

Here, in the present embodiment, the terminal holder 122 of the housing 120 is provided with a heat-drawing component accommodation chamber 122a explained below, for each of the connector terminals 110. Each of the heat-drawing component accommodation chambers 122a is integrally formed with the outer wall of the terminal holder 122. The heat-drawing component accommodation chamber 122a is provided in a tubular shape, specifically a cylindrical tubular shape, extending in the above-mentioned contact direction D12, such that one end side opens toward the outside and the other end side opens toward the electric wire connection portion 112 of the connector terminal 110.

The heat-drawing component 130 is accommodated in the heat-drawing component accommodation chamber 122a in the contact direction D12 through an opening 122a-1 at one end side of the heat-drawing component accommodation chamber 122a that is open toward the outside of the terminal holder 122. The heat-drawing component 130 protrudes from an opening 122a-2 at the other end side of the heat-drawing component accommodation chamber 122a to come into contact with the electric wire terminal W111, and dissipates heat to and comes into contact with an inner circumferential surface 122a-3 of the heat-drawing component accommodation chamber 122a, i.e., an adjacent portion to which heat is dissipated. This heat-drawing component 130 is a cylindrical columnar member corresponding to the cylindrical tubular shape of the heat-drawing component accommodation chamber 122a. The heat-drawing component 130 is accommodated in the heat-drawing component accommodation chamber 122a such that an outer circumferential surface 131 is in contact, over the entire circumference, with the inner circumferential surface 122a-3 in the cylindrical tubular shape.

In the present embodiment, the heat-drawing component 130 is fastened and fixed, by the bolt 140, together with the electric wire connection portion 112 of the connector terminal 110 and the electric wire terminal W111. With this co-fastening fixation, the heat-drawing component 130 is attached such that the electric wire terminal W111 is sandwiched between the electric wire connection portion 112 of the connector terminal 110 and the heat-drawing component 130. This heat-drawing component 130 is provided with a through hole 132 for the bolt 140.

During assembly, as illustrated in FIG. 4, after the connector terminals 110 are inserted in the insertion direction D11, the electric wire terminals W111 are inserted in the electric wire insertion direction D111 that is the same as this insertion direction D11, and the heat-drawing components 130 are inserted into the heat-drawing component accommodation chambers 122a in the contact direction D12. As a result, inside the terminal holder 122, the female screw hole 112a of the electric wire connection portion 112, the terminal hole W111a of the electric wire terminal W111, and the through hole 132 of the heat-drawing component 130 are in communication with each other. Then, the bolt 140 penetrates through the through hole 132 of the heat-drawing component 130 and the terminal hole W111a of the electric wire terminal W111 to be screwed into the female screw hole 112a of the electric wire connection portion 112. With this fastening of the bolt, the heat-drawing component 130 is fastened and fixed together with the electric wire connection portion 112 of the connector terminal 110 and the electric wire terminal W111. After the heat-drawing components 130 are attached, the openings 122a-1 on the outer sides of the two heat-drawing component accommodation chambers 122a are closed by a single cap member 122b, as illustrated in FIGS. 2 and 3.

The heat-drawing components 130 thus fixed protrude from the openings 122a-2 of the heat-drawing component accommodation chambers 122a on the side of the connector terminals 110 to come into contact with the electric wire terminals W111, and the outer circumferential surfaces 131 come into contact with the inner circumferential surfaces 122a-3 of the heat-drawing component accommodation chambers 122a. Then, when heat is generated at the terminal portions 111 of connector terminals 110 that are contact portions for contact with the mating connector terminals and that have a high resistance during charging, temperature rise due to heat at that time is alleviated via the heat-drawing components 130 as follows.

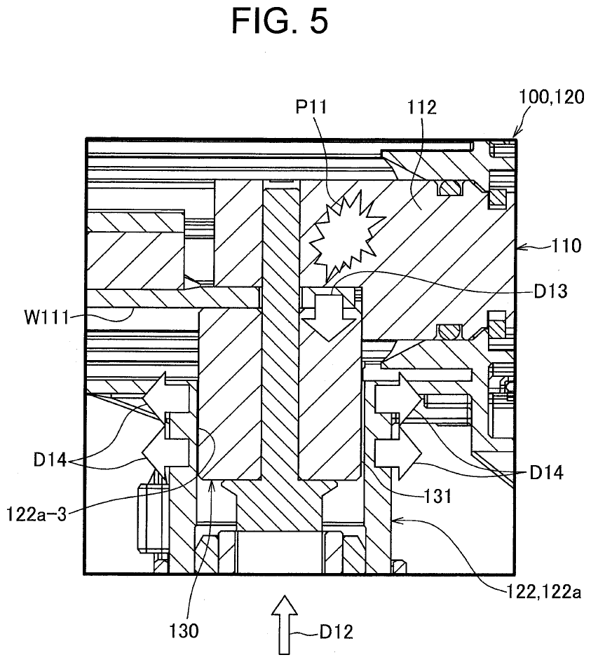

FIG. 5 is a schematic diagram illustrating how the heat-drawing components illustrated in FIGS. 2 to 4 alleviate temperature rise due to heat during charging. FIG. 5 illustrates an enlarged view of a periphery of the heat-drawing component 130 in the cross-sectional view of FIG. 2.

When heat P11 generated in the connector terminal 110 during charging by the charge inlet 100 is transmitted to the electric wire connection portion 112, the heat P11 is absorbed by the heat-drawing component 130, as illustrated in FIG. 5. Specifically, the heat P11 transmitted to the electric wire connection portion 112 is indirectly absorbed, in a heat-drawing direction D13 along the contact direction D12 of the heat-drawing component 130 for contact with the electric wire terminal W11, by the heat-drawing component 130 via the electric wire terminal W111 in contact with the electric wire connection portion 112. Then, the heat-drawing component 130 dissipates, in a heat dissipation direction D14, the absorbed heat P11 through the outer circumferential surface 131 to the inner circumferential surface 122a-3 of the heat-drawing component accommodation chamber 122a that is the adjacent portion. The dissipated heat P11 disperses via the terminal holder 122 to each portion of the housing 120. According to the heat absorption, heat dissipation, and dispersion, temperature rise at the charge inlet 100 during charging is alleviated.

Here, in the present embodiment, a conductive heat-drawing component made of a conductive material and a non-conductive heat-drawing component made of a non-conductive material are prepared as the heat-drawing component 130. Examples of conductive materials include conductive metals such as copper (Cu) and aluminum (Al). Examples of non-conductive materials include resins such as various kinds of plastics. Furthermore, in the housing 120, the connector terminal 110 is accommodated in a state-switchable manner in any one of a first state, a second state, and a third state. The first state is a state in which conductive heat-drawing components are installed as the heat-drawing components 130 to absorb heat from the connector terminals 110. The second state is a state in which non-conductive heat-drawing components are installed as the heat-drawing components 130 to absorb heat from the connector terminals 110. The third state is a state in which the heat-drawing components 130 are not installed, and heat absorption during charging is not actively performed. In the third state, with the contacting portion between the connector terminals 110 and the housing 120, the electric wire terminals W111, and the DC electric wires W11, heat absorption is performed more slowly than when the heat-drawing components 130 are provided.

Before the effects obtained with the charge inlet 100 according to the embodiment described above are explained, a comparative example of the present embodiment will be explained.

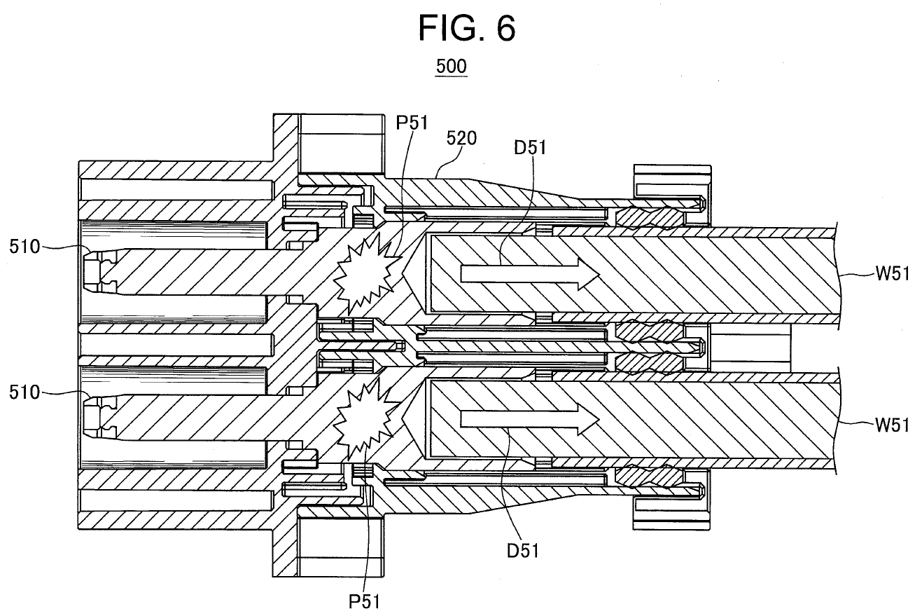

FIG. 6 is a diagram illustrating a comparative example for comparison with the charge inlet illustrated in FIGS. 1 to 5. In FIG. 6, a charge inlet 500 according to a comparative example is illustrated in a cross section taken along a DC electric wire W51 extending from the charge inlet 500. In the cross-sectional view of FIG. 6, the right side of FIG. 6 is a side where the DC electric wires W51 extend, and the left side of FIG. 6 is a connection side for connection with the mating connector.

In the charge inlet 500 according to the comparative example, the conductors of the DC electric wires W51 are directly connected to the connector terminals 510 by soldering. In this comparative example, members similar to the heat-drawing components 130 of the above-described embodiment are not provided in the housing 520. The heat P51 that is generated during the contact portion between the connector terminals 510 and the mating connector terminals during charging and transmitted inside the connector terminals 510 is mainly absorbed, transmitted, and dispersed by the DC electric wires W51 along its extending direction D51. Accordingly, temperature rise during charging is alleviated. In order to sufficiently alleviate such temperature rise, in this comparative example, the diameter of the DC electric wires W51 is increased to reduce the connection resistance with the connector terminals 510 and improve the heat-drawing ability with the DC electric wires W51. However, as the diameter of the DC electric wires W51 extending from the charge inlet 500 increase, not only the weight and cost around the inlet increase, but also the inlet may increase in the size in order to allow the DC electric wires W51 having the large diameter to pass inside the housing 520.

Compared to the charge inlet 500 of the comparative example described above, the charge inlet 100 according to the embodiment explained with reference to FIGS. 1 to 5 provides the following effects. In the present embodiment, the heat P11 generated in the connector terminals 110 is absorbed by the heat-drawing components 130. The heat-drawing components 130 come into contact, in the contact direction D12 that crosses the insertion direction D11 of the connector terminal 110, with the electric wire terminals W111, which is in contact as intermediate members with the electric wire connection portions 112 that are heat sources of the connector terminal 110. Due to this contact, the heat P11 of the connector terminals 110 is drawn from the connector terminals 110 by the heat-drawing components 130 before the heat P11 is transmitted to the DC electric wires W11. Therefore, temperature rise in the charge inlet 100 during charging can be alleviated without changing the size of the DC electric wires W11 connected to the connector terminals 110. Furthermore, since the size of the DC electric wires W11 is maintained as is, the increase in the weight and cost around the inlet and the increase in the size of the inlet can be alleviated. As described above, according to the charge inlet 100 of the present embodiment, temperature rise during charging can be alleviated while alleviating the increase in the weight and cost around the inlet and the increase in the size of the inlet.

Here, in the present embodiment, the heat-drawing components 130 are also in contact with the adjacent portion, i.e., the inner circumferential surface 122a-3 of the heat-drawing component accommodation chamber 122a, when the heat-drawing components 130 are accommodated in the housing 120. The heat-drawing components 130 dissipate heat absorbed from the electric wire connection portions 112 that are the heat sources to the inner circumferential surfaces 122a-3 of the heat-drawing component accommodation chambers 122a that are the adjacent portions. According to this configuration, the size of the heat-drawing components 130 can be reduced while alleviating temperature rise during charging by heat dissipation through the heat-drawing components 130.

Furthermore, in the present embodiment, the cylindrical heat-drawing component accommodation chambers 122a are provided to connect the inside and outside of the housing 120. The heat-drawing components 130 are accommodated in the heat-drawing component accommodation chambers 122a to protrude from the openings 122a-2 to absorb heat, and come into contact with the inner circumferential surfaces 122a-3 of the heat-drawing component accommodation chambers 122a to dissipate heat. According to this configuration, heat can be dissipated to areas with large heat capacity, i.e., the inner circumferential surfaces 122a-3 of the heat-drawing component accommodation chambers 122a provided in the housing 120, and therefore, temperature rise during charging can be further alleviated. The heat-drawing component accommodation chambers 122a are provided in a tubular shape that connects the inside and outside of the housing 120, so that the heat-drawing components 130 can be attached, detached, and accommodated with a high work efficiency.

Furthermore, in the present embodiment, the heat-drawing component accommodation chambers 122a are formed in the cylindrical tubular shape, so that, when the heat-drawing components 130 are accommodated, the outer circumferential surfaces 131 of the heat-drawing components 130 in the cylindrical columnar shape are in contact, over the entire circumference, with the inner circumferential surfaces 122a-3 of the heat-drawing component accommodation chambers 122a. According to this configuration, the outer circumferential surfaces 131 of the heat-drawing component 130 in the cylindrical columnar shape can be used, over the entire circumference, as heat dissipation surfaces for the inner circumferential surfaces 122a-3 of the heat-drawing component accommodation chambers 122a in the cylindrical tubular shape, so that the area of heat dissipation can be increased to improve the heat dissipation performance.

Furthermore, in the present embodiment, the heat-drawing components 130 indirectly absorb heat from the heat sources, i.e., the electric wire connection portions 112 of the connector terminals 110, via the electric wire terminals W111 fastened and fixed together with the electric wire connection portions 112 by the bolts 140. According to this configuration, the connection of the connector terminal 110 to the electric wire and the contacting and fixing of the heat-drawing component 130 with the connector terminal 110 are made by fastening of the bolt in a single step, so that the efficiency of the assembly work can be improved.

Furthermore, in the present embodiment, the conductive heat-drawing component and the non-conductive heat-drawing component are prepared as the heat-drawing component 130. In the housing 120, the connector terminal 110 is accommodated in a state-switchable manner in any one of the first state in which the conductive heat-drawing components are installed, the second state in which the non-conductive heat-drawing components are installed, and the third state in which the heat-drawing components 130 are not installed.

In electric vehicles (EVs), plug-in hybrid electric vehicles (PHVs), and the like, the current performance required during charging (referred to as power requirements) differ depending on the vehicle type. As typical power requests, there are three types as explained below. The first type is a performance-oriented type for a vehicle equipped with a large battery and allows rapid charging with a high current, and requires sufficient control of temperature rise while allowing for a certain amount of cost increase. The second type is a cost-oriented type for a vehicle that performs rapid charging using a high current, but cost reduction is required while allowing a certain degree of temperature rise. The third type is a small current type with a small battery and a low charge current, so that there is no need to care about temperature rise during charging. According to the above-described configuration, the accommodation state of the connector terminals 110 is switched by selectively installing the conductive heat-drawing components and the non-conductive heat-drawing components or choosing not to install the heat-drawing components 130, the heat-drawing components 130 can be installed appropriately depending on the three types of power requests explained above.

Note that the embodiments described above merely show typical forms of the charge inlet. The charge inlet is not limited thereto, and can be implemented with various modifications.

For example, in the embodiment described above, the charge inlet 100 used in electric vehicles (EVs), plug-in hybrid electric vehicles (PHVs), and the like for battery charging is exemplified as an example of the charge inlet. However, the charge inlet is not limited thereto, and as long as it has a connection mechanism with a mating connector for charging, its specific application is not particularly limited.

Furthermore, in the embodiment described above, as an example of the heat-drawing component, the heat-drawing component 130 is explained that draws heat by coming into contact with the electric wire terminal W111, i.e., the intermediate member, that is in contact with the heat source in the connector terminal 110. However, the heat-drawing component is not limited thereto, and may be one that directly comes into contact with the heat source of the connector terminal to perform heat-drawing.

Furthermore, in the embodiment described above, as an example of a heat-drawing component, the heat-drawing component 130 is explained that dissipates heat to the adjacent portion, i.e., the inner circumferential surface 122a-3 of the heat-drawing component accommodation chamber 122a, provided in the housing 120 by coming into contact with the inner circumferential surface 122a-3. However, the heat-drawing component is not limited thereto, and may be a component that dissipates heat dissipation into the air without contacting anything other than the heat source of the connector terminal or the intermediate member. However, as described above, the heat-drawing component 130 that dissipates heat dissipation by coming into contact with a certain adjacent portion can further alleviate the temperature rise during charging.

Furthermore, in the embodiment described above, as an example of an adjacent portion which the heat-drawing component comes into contact with and dissipates heat to, the inner circumferential surface 122a-3 of the heat-drawing component accommodation chamber 122a in the tubular shape provided on the terminal holder 122 is explained, but the adjacent portion is not limited thereto. The adjacent portion for the heat-drawing component is not particularly limited as long as it is a portion which the heat-drawing component can come into contact with and dissipate heat to. However, by making the cylindrical inner circumferential surface 122a-3 of the heat-drawing component accommodation chamber 122a the adjacent portion for the heat-drawing component 130, not only the temperature rise can be alleviated but also the heat-drawing component 130 can be attached, detached, and accommodated with a high work efficiency, as described above.

Furthermore, in the embodiment described above, as an example of a heat-drawing component accommodation chamber, the heat-drawing component accommodation chamber 122a formed in a cylindrical tubular shape is explained, and as an example of a heat-drawing component, the cylindrical heat-drawing component 130 is explained. However, the shapes of the heat-drawing component accommodation chamber and the heat-drawing component are not limited to the cylindrical tubular and cylindrical columnar shapes, and as long as the outer circumferential surface of the heat-drawing component can come into contact with the inner circumferential surface of the cylindrical heat-drawing component accommodation chamber to dissipate heat, the shapes of the heat-drawing component accommodation chamber and the heat-drawing component may be any shapes. However, according to the heat-drawing component accommodation chamber 122a in the cylindrical tubular shape and the heat-drawing component 130 in the cylindrical columnar shape, the heat dissipation performance can be improved by increasing the heat dissipation area by the heat-drawing component 130, as described above.

Furthermore, in the embodiment described above, as an example of a heat-drawing component, the heat-drawing component 130 that indirectly absorbs heat from the connector terminal 110 such that the heat-drawing component 130 is fastened and fixed together with the electric wire terminal W111, i.e., the intermediate member, and the electric wire connection portion 112, i.e., the heat source is explained. However, the heat-drawing component is not limited thereto, and even if heat is drawn through the intermediate member, the specific form of the member is not particularly limited. Further, the fixing method is not limited to fastening and fixing the heat-drawing component and the intermediate member together, and the heat-drawing component and the intermediate member may be fixed separately. However, by fastening and fixing the heat-drawing component 130 together with the electric wire terminal W111 that is the intermediate member, the connection of the electric wire and the fixing of the heat-drawing component 130 can be made by fastening of the bolt in a single step, so that the efficiency of the assembly work can be improved, as described above.

Furthermore, in the embodiment described above, as an example of a charge inlet, the charge inlet 100 in which the connector terminal 110 is accommodated in a state-switchable manner in three types of states, i.e., the first to third states, is explained. The first state is a state in which conductive heat-drawing components are installed with the connector terminals 110. The second state is a state in which non-conductive heat-drawing components are installed with the connector terminals 110. The third state is a state in which the heat-drawing components 130 are not installed. However, the charge inlet is not limited thereto, and may be, e.g., a charge inlet in which a uniquely determined heat-drawing component is installed together with a connector terminal at all times. However, switching of the state as described above can appropriately satisfy the power requests of electric vehicles (EVs) and plug-in hybrid electric vehicles (PHVs), such as performance-oriented first type, cost-oriented second type, and small current type, as described above.

### LIST OF REFERENCE SIGNS

100 charge inlet
101 DC socket
102 AC socket
110 connector terminal
111 terminal portion
112 electric wire connection portion (heat source)
112a female screw hole
120 housing
121 main body housing
122 terminal holder
122a heat-drawing component accommodation chamber
122a-1, 122a-2 opening
122a-3 inner circumferential surface (adjacent portion)
122b cap member
130 heat-drawing component
131 outer circumferential surface
132 through hole
140 bolt
D11 insertion direction
D12 contact direction
D13 heat-drawing direction
D14 heat dissipation direction
P11 heat
W11 DC electric wire
W111 electric wire terminal (intermediate member)
W111a terminal hole
W12 AC electric wire W

What is claimed is:

1. A charge inlet comprising:
a connector terminal connected to a mating connector terminal for charging;
a housing in which the connector terminal is inserted in a predetermined insertion direction and is accommodated in such a state that the connector terminal can connect to the mating connector terminal; and
a heat-drawing component detachably accommodated in the housing in such a state that the heat-drawing component is in contact, in a contact direction that crosses the insertion direction, with a heat source of the connector terminal that is away, in a direction opposite to the insertion direction, from a terminal portion of the connector terminal for connecting with the mating connector terminal, or with an intermediate member that is in contact with the heat source, the heat-drawing component being configured to absorb heat of the heat source when the heat-drawing component is accommodated in the housing.

2. The charge inlet according to claim 1, wherein when the heat-drawing component is accommodated in the housing, the heat-drawing component is also in contact with a predetermined adjacent portion to dissipate, to the adjacent portion, the heat absorbed from the heat source.

3. The charge inlet according to claim 2, wherein the housing is provided with a heat-drawing component accommodation chamber in a tubular shape integrally formed with an outer wall of the housing, the heat-drawing component accommodation chamber extending in the contact direction such that one end side of the heat-drawing component accommodation chamber is open toward an outside, and another end side of the heat-drawing component accommodation chamber is open toward the heat source of the connector terminal, and
the heat-drawing component is accommodated in the contact direction into the heat-drawing component accommodation chamber through an opening on the one end side, the heat-drawing component protruding from the opening on the other end side to absorb heat from the heat source, an inner circumferential surface of the heat-drawing component accommodation chamber being brought into contact with the adjacent portion to dissipate heat.

4. The charge inlet according to claim 3, wherein the heat-drawing component accommodation chamber is formed in a cylindrical tubular shape, and
the heat-drawing component is a cylindrical columnar member that is accommodated in the heat-drawing component accommodation chamber in such a state that an outer circumferential surface of the cylindrical columnar member is in contact, over an entire circumference, with the inner circumferential surface of the cylindrical tubular shape of the heat-drawing component accommodation chamber.

5. The charge inlet according to claim 1, wherein the connector terminal includes, inside the housing, an electric wire connection portion configured to be fastened, by a bolt, to an electric wire terminal provided at an end portion of an electric wire extending in the insertion direction, and
the heat-drawing component is fastened, by the bolt, to the electric wire connection portion together with the electric wire terminal in such a state that the heat-drawing component is in contact with the electric wire terminal serving as the intermediate member, so that
the heat-drawing component indirectly absorbs heat, via the electric wire terminal, from the electric wire connection portion that is the heat source.

6. The charge inlet according to claim 1, wherein a conductive heat-drawing component made of a conductive material and a non-conductive heat-drawing component made of a non-conductive material are prepared as the heat-drawing component, and
in the housing, the connector terminal is accommodated in a state-switchable manner in any one of a first state in which the conductive heat-drawing component is installed, a second state in which the non-conductive heat-drawing component is installed, and a third state in which the heat-drawing component is not installed.
